(19) United States
(12) Patent Application Publication
(10) Pub. No.: US 2025/0297357 A1
(43) Pub. Date: Sep. 25, 2025

(54) DEPOSITION MASK AND METHOD OF MANUFACTURING THE SAME

(71) Applicant: Samsung Display Co., LTD., Yongin-si (KR)

(72) Inventors: Jin Woo LEE, Yongin-si (KR); Sung Woon KIM, Yongin-si (KR); Jeong Kuk KIM, Yongin-si (KR); Duck Jung LEE, Yongin-si (KR); Sug Woo JUNG, Yongin-si (KR); Jun Ho JO, Yongin-si (KR)

(73) Assignee: Samsung Display Co., LTD., Yongin-si (KR)

(21) Appl. No.: 18/977,130

(22) Filed: Dec. 11, 2024

(30) Foreign Application Priority Data
Mar. 19, 2024 (KR) 10-2024-0037968

(51) Int. Cl. C23C 16/04; C23C 14/04; H10K 59/10; H10K 71/16

(52) U.S. Cl. CPC C23C 16/042; C23C 14/042; H10K 59/10; H10K 71/166

(57) ABSTRACT

A deposition mask includes a wafer substrate including a first portion, a second portion below the first portion, and a plurality of cell opening areas spaced apart from each other, a plurality of deformation resistance layers disposed on the wafer substrate to overlap the plurality of cell opening areas in a plan view and corresponding one-to-one to the plurality of cell opening areas, and an inorganic layer disposed on the wafer substrate to cover the wafer substrate and the plurality of deformation resistance layers. In each of the plurality of cell opening areas, a plurality of first opening patterns penetrating the first portion, a corresponding one of the plurality of deformation resistance layers, and the inorganic layer in a thickness direction are defined, and a plurality of second opening patterns overlapping the plurality of cell opening areas in a plan view and penetrating the second portion in the thickness direction are defined.

### CROSS-REFERENCE TO RELATED APPLICATION(S)

This application claims priority to and benefits of Korean Patent Application No. 10-2024-0037968 under 35 U.S.C. § 119, filed on Mar. 19, 2024, in the Korean Intellectual Property Office (KIPO), the entire contents of which are incorporated herein by reference.

### BACKGROUND

### 1. Technical Field

The disclosure relates to a deposition mask and a method of manufacturing the same.

2. Description of the Related Art

An organic light emitting display device may be used in a mobile device such as a smartphone, a computer, or a tablet personal computer, or an electronic device such as television, an outdoor billboard, or an exhibition display.

An organic light emitting display device may include an anode electrode and a cathode electrode disposed on a substrate, and an organic light emitting layer interposed between the anode electrode and the cathode electrode. The organic light emitting layer may be formed using a deposition mask.

### SUMMARY

The disclosure relates to a deposition mask for depositing an organic light emitting layer and a method of manufacturing the same.

A deposition mask according to embodiments of the disclosure may include a wafer substrate including a first portion, a second portion below the first portion, and a plurality of cell opening areas spaced apart from each other; a plurality of deformation resistance layers disposed on the wafer substrate to overlap the plurality of cell opening areas in a plan view and corresponding one-to-one to the plurality of cell opening areas; and an inorganic layer disposed on the wafer substrate to cover the wafer substrate and the plurality of deformation resistance layers. In each of the plurality of cell opening areas, a plurality of first opening patterns penetrating the first portion, a corresponding one of the plurality of deformation resistance layers, and the inorganic layer in a thickness direction may be defined, and a plurality of second opening patterns penetrating the second portion in the thickness direction may be defined to overlap the plurality of cell opening areas in a plan view.

In some embodiments, the plurality of second opening patterns may be provided to correspond one-to-one to the plurality of cell opening areas.

In some embodiments, in each of the plurality of cell opening areas, one of the plurality of second opening patterns and two or more of the plurality of first opening patterns may overlap each other in a plan view.

In some embodiments, in each of the plurality of cell opening areas, the plurality of deformation resistance layers may be disposed on the wafer substrate in an area between the plurality of first opening patterns.

In some embodiments, in an area between the plurality of cell opening areas, an upper surface of the wafer substrate may be directly covered by the inorganic layer.

In some embodiments, the plurality of deformation resistance layers may include a material having a thermal expansion coefficient less than or equal to about 10 in/in° C. and a Young's modulus greater than or equal to about 300 GPa.

In some embodiments, the plurality of deformation resistance layers may include graphene.

In some embodiments, the inorganic layer may include at least one of silicon nitride, silicon oxide, and silicon oxynitride.

In some embodiments, in each of the plurality of cell opening areas, a sum of a thickness of the corresponding one of the plurality of deformation resistance layers and a thickness of the inorganic layer may be less than or equal to about 1 micrometer.

In some embodiments, the deposition mask may further include an alignment groove recessed in a direction from an upper surface of the inorganic layer toward the wafer substrate.

In some embodiments, the alignment groove may not overlap the plurality of first opening patterns in a plan view.

In some embodiments, the alignment groove may be located between adjacent ones of the plurality of first opening patterns in each of the plurality of cell opening areas.

In some embodiments, the first portion and the second portion may be formed integrally.

A method of manufacturing a deposition mask according to embodiments of the disclosure may include forming a pre-deformation resistance layer on a wafer substrate including a first portion, a second portion below the first portion, and a plurality of cell opening areas spaced apart from each other, patterning the pre-deformation resistance layer to form a plurality of deformation resistance layers defining a plurality of first pre-opening patterns exposing an upper surface of the wafer substrate in each of the plurality of cell opening areas, forming a pre-inorganic layer on the wafer substrate to cover the wafer substrate and the plurality of deformation resistance layers, forming a plurality of first opening patterns by removing a portion of the pre-inorganic layer and the first portion in an area overlapping the plurality of first pre-opening patterns in a plan view, and forming a plurality of second opening patterns by removing a portion of the second portion in an area overlapping the plurality of cell opening areas in a plan view.

In some embodiments, the plurality of deformation resistance layers may include a material having a thermal expansion coefficient less than or equal to about 10 in/in° C. and a Young's modulus greater than or equal to about 300 GPa.

In some embodiments, the plurality of deformation resistance layers may include graphene.

In some embodiments, the plurality of second opening patterns may be provided to correspond one-to-one to the plurality of cell opening areas.

In some embodiments, in each of the plurality of cell opening areas, one of the plurality of second opening patterns and two or more of the plurality of first opening patterns may overlap each other in a plan view.

In some embodiments, the method of manufacturing the deposition mask may further include forming an alignment groove recessed in a direction from an upper surface of the inorganic layer toward the wafer substrate.

### BRIEF DESCRIPTION OF THE DRAWINGS

The accompanying drawings, which are included to provide a further understanding of the disclosure, and are incorporated in and constitute a part of this specification, illustrate embodiments of the disclosure, and, together with the description, serve to explain principles of the disclosure.

FIG. 1 is a plan view for explaining a deposition mask according to embodiments of the disclosure.

FIG. 2 is a schematic cross-sectional view taken along line I1-I1′ in FIG. 1.

FIG. 3 is an enlarged plan view of area AA of FIG. 1.

FIG. 4 is a schematic cross-sectional view taken along line I2-I2′ in FIG. 3.

FIG. 5 is a schematic diagram for explaining a pixel according to embodiments of the disclosure.

FIG. 6 is a schematic cross-sectional view for explaining a display panel including the pixel of FIG. 5.

FIGS. 7 to 9 are schematic cross-sectional views for explaining a method of manufacturing the display panel of FIG. 6 using the deposition mask of FIG. 1.

FIG. 10 is a flowchart for explaining a method of manufacturing the deposition mask of FIG. 1.

FIGS. 11 to 15 are schematic cross-sectional views for explaining a method of manufacturing the deposition mask of FIG. 1.

### DETAILED DESCRIPTION OF THE EMBODIMENTS

Hereinafter, embodiments of the disclosure will be described in more detail with reference to the accompanying drawings. It should be noted that in the following description, only the parts necessary to understand the operation of the disclosure will be described, and descriptions of other parts will be omitted in order to not obscure the gist of the disclosure. In addition, the disclosure is not limited to the embodiments described herein and may be embodied in other forms. The embodiments described herein are provided merely to explain in detail enough to enable those skilled in the art to readily implement the technical idea of the disclosure.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Terms used herein are for describing specific embodiments and are not intended to limit the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Various embodiments are described with reference to drawings schematically illustrating ideal embodiments. Accordingly, it will be expected that shapes may vary, for example, according to tolerances and/or manufacturing techniques. Therefore, the embodiments disclosed herein cannot be construed as being limited to shown specific shapes, and should be interpreted as including, for example, changes in shapes that occur as a result of manufacturing. As described above, the shapes shown in the drawings may not show actual shapes of areas of a device, and the disclosure is not limited thereto.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

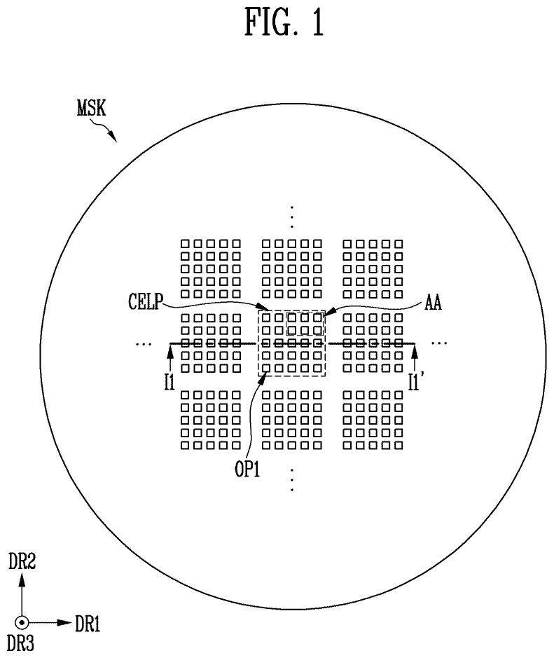

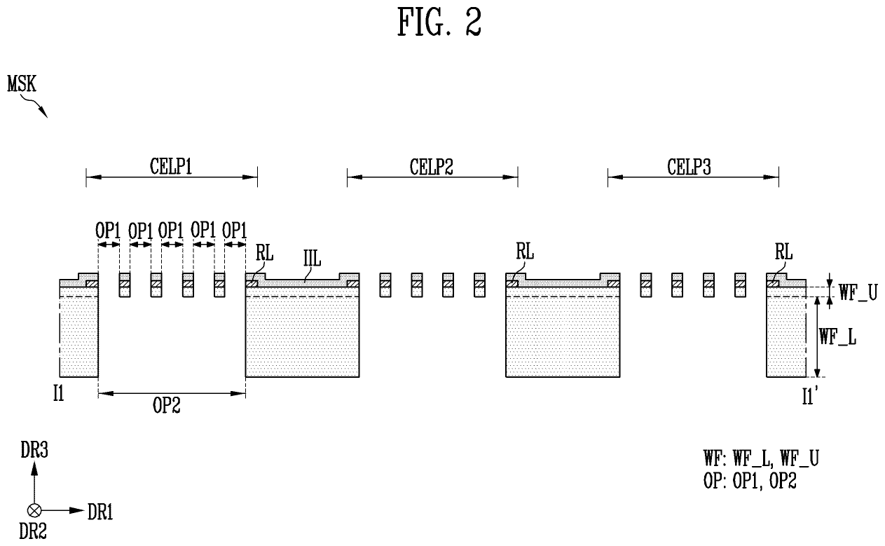

FIG. 1 is a plan view for explaining a deposition mask according to embodiments of the disclosure. FIG. 2 is a schematic cross-sectional view taken along line I1-I1′ in FIG. 1.

Referring to FIGS. 1 and 2, a deposition mask MSK may include a wafer substrate WF, multiple deformation resistance layers RL, and an inorganic layer IIL.

The wafer substrate WF may include at least silicon. The wafer substrate WF may have a circular shape in a plan view. However, the material constituting the wafer substrate WF and the planar shape of the wafer substrate WF are not limited thereto. The wafer substrate WF may be made of various materials and may have various planar shapes.

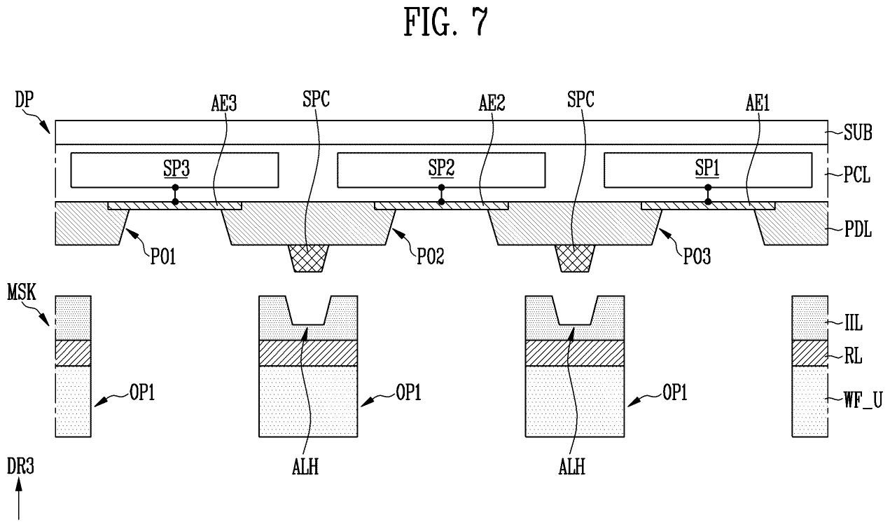

The wafer substrate WF may include a cell opening area CELP. The deposition mask MSK may be aligned to face a deposition target DP (shown in FIG. 7). The deposition mask MSK may block a deposition material in some areas and may not block the deposition material in other areas. Accordingly, the deposition material may be selectively deposited only on specific areas of the deposition target. The cell opening area CELP may be an area where the deposition material is not blocked.

For example, multiple first opening patterns OP1 and a second opening pattern OP2 overlapping the first opening patterns OP1 may be provided in the cell opening area CELP. The deposition material may be provided to the deposition target DP through the second opening pattern OP2 and the first opening patterns OP1.

Using one deposition mask MSK, deposition may be performed on multiple deposition targets simultaneously. In an embodiment, multiple cell opening areas CELP may be provided. For example, the cell opening areas CELP may be arranged in a first direction DR1 and a second direction DR2 intersecting the first direction DR1 and may be spaced apart from each other. In case that multiple cell opening areas CELP are provided, one second opening pattern OP2 and multiple first opening patterns OP1 overlapping the second opening pattern OP2 may be provided in each of the cell opening areas CELP. For example, in FIG. 2, among the cell opening areas CELP, first to third cell opening areas CELP1, CELP2, and CELP3 are shown. One second opening pattern OP2 and multiple first opening patterns OP1 overlapping the second opening pattern OP2 may be provided in each of the first to third cell opening areas CELP1, CELP2, and CELP3.

Corresponding to the cell opening areas CELP, the deformation resistance layers RL may be disposed on the wafer substrate WF. The deformation resistance layers RL may correspond one-to-one to the cell opening areas CELP. For example, one deformation resistance layer RL may be disposed in one cell opening area CELP.

The inorganic layer IIL may be disposed on the wafer substrate WF to cover the wafer substrate WF and the deformation resistance layers RL. The inorganic layer IIL may include an inorganic insulating material. For example, the inorganic layer IIL may include at least one of silicon nitride, silicon oxide, and silicon oxynitride, but embodiments are not limited thereto.

Hereinafter, the first and second opening patterns OP1 and OP2 will be described.

In each of the cell opening areas CELP, multiple first opening patterns OP1 penetrating a first portion WF_U of the wafer substrate WF, a corresponding deformation resistance layer RL, and the inorganic layer IIL in a third direction DR3 may be defined. For example, the first opening patterns OP1 may be provided in one cell opening area CELP.

Multiple second opening patterns OP2 penetrating a second portion WF_L of the wafer substrate WF in the third direction DR3 may be defined to overlap the cell opening areas CELP in a plan view. For example, the second opening patterns OP2 may be provided to correspond one-to-one to the cell opening areas CELP. Here, the second portion WF_L of the wafer substrate WF may be a portion below the first portion WF_U of the wafer substrate WF. The first portion WF_U and the second portion WF_L may be formed integrally to form the wafer substrate WF.

In each of the cell opening areas CELP, one second opening pattern OP2 and two or more first opening patterns OP1 may overlap each other in a plan view. For example, in the first cell opening area CELP1 shown in FIG. 2, one second opening pattern OP2 may overlap the first opening patterns OP1 in a plan view. In an embodiment, one second opening pattern OP2 and the first opening patterns OP1 may be formed integrally. Accordingly, the deposition material may be provided to the deposition target through the first and second opening patterns OP1 and OP2. The description of the first cell opening area CELP1 described above may be similarly applied to each of the second and third cell opening areas CELP2 and CELP3.

In some embodiments, the first opening patterns OP1 provided in each of the cell opening areas CELP may be partitioned by a first laminated structure including the first portion WF_U, the deformation resistance layer RL, and the inorganic layer IIL. Since the first laminated structure does not include the second portion WF_L, the first laminated structure may have a relatively small thickness. Here, the deformation resistance layer RL may be disposed on the wafer substrate WF in an area between the first opening patterns OP1. The deformation resistance layer RL may serve to compensate for the relatively small thickness of the first laminated structure. For example, the deformation resistance layer RL may serve to provide deformation resistance (for example, resistance to deformation by heat and/or deformation by external force) to the first laminated structure.

To this end, the deformation resistance layer RL may include a material having a thermal expansion coefficient of less than or equal to about 10 in/in° C. and a Young's modulus of greater than or equal to about 300 GPa. For example, the deformation resistance layer RL may include graphene, but embodiments are not limited thereto.

As shown in FIG. 2, the second portion WF_L having a relatively large thickness may be provided in an area between the cell opening areas CELP. Accordingly, the deposition mask MSK may secure sufficient deformation resistance in the area between the cell opening areas CELP. Therefore, the deformation resistance layer RL may not be disposed in the area between the cell opening areas CELP (for example, an area between the first cell opening area CELP1 and the second cell opening area CELP2, and an area between the second cell opening area CELP2 and the third cell opening area CELP3). In other words, in the area between the cell opening areas CELP, an upper surface of the wafer substrate WF may be directly covered by the inorganic layer IIL.

In some embodiments, the thickness of the second portion WF_L in the third direction DR3 may be greater than the sum of the thickness of the first portion WF_U in the third direction DR3, the thickness of the deformation resistance layer RL in the third direction DR3, and the thickness of the inorganic layer IIL in the third direction DR3. Here, the sum of the thickness of the deformation resistance layer RL in the third direction DR3 and the thickness of the inorganic layer IIL in the third direction DR3 may be less than or equal to about 1 micrometer. Accordingly, in a deposition process using the deposition mask MSK, it may be possible to prevent the shadow phenomenon of the deposition material from occurring.

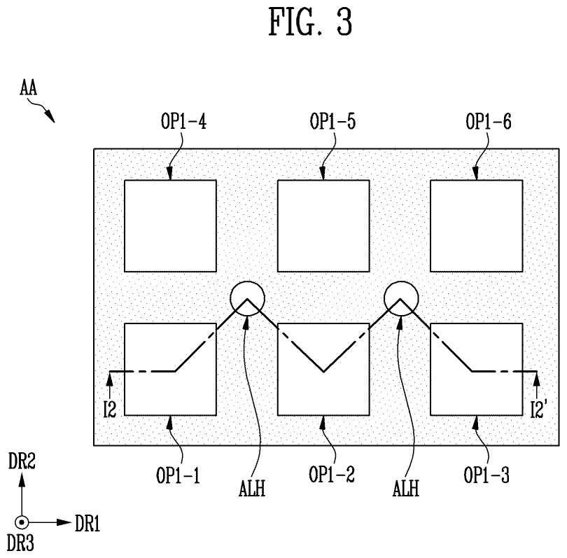

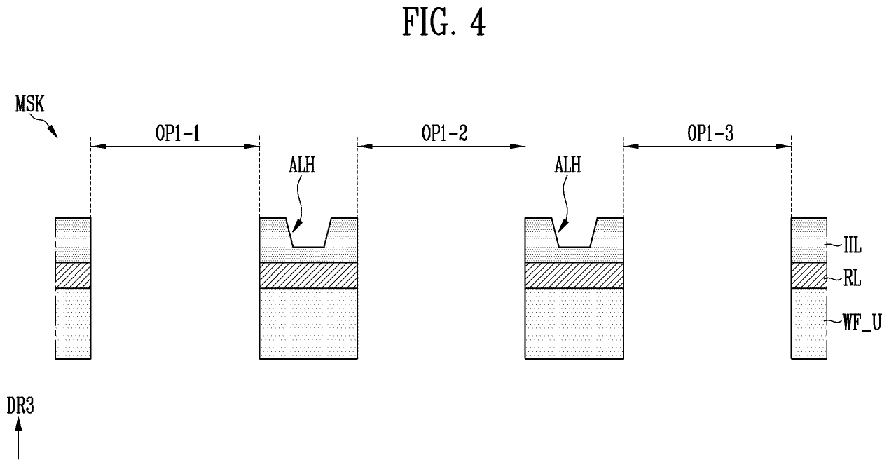

FIG. 3 is an enlarged plan view of area AA of FIG. 1. FIG. 4 is a schematic cross-sectional view taken along line I2-I2′ in FIG. 3.

Referring to FIGS. 3 and 4, FIG. 3 is an enlarged plan view showing an area in one cell opening area CELP among the cell opening areas CELP of FIG. 1. As described above with reference to FIGS. 1 and 2, one second opening pattern OP2 may be provided in each of the cell opening areas CELP. Accordingly, in the cross-sectional view of FIG. 4, it can be considered that the second opening pattern OP2 is provided below the first portion WF_U.

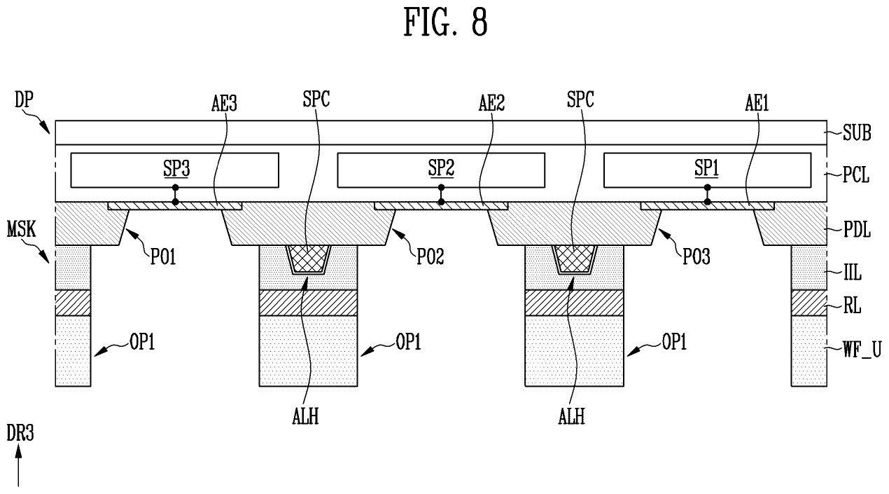

In some embodiments, the deposition mask MSK may further include an alignment groove ALH that is recessed from an upper surface of the inorganic layer IIL toward a direction opposite to the third direction DR3. In case that the deposition mask MSK is aligned with the deposition target DP (shown in FIGS. 7 and 8), the alignment groove ALH may accommodate a protrusion SPC (shown in FIGS. 7 and 8) formed on the deposition target DP. To this end, the alignment groove ALH may have a shape corresponding to the protrusion formed on the deposition target and may be formed at a position corresponding to the position where the protrusion is formed. For example, the alignment groove ALH may have various shapes corresponding to the shape of the protrusion. Accordingly, it may be possible to prevent the deposition mask MSK from being deformed by the protrusion.

The alignment groove ALH may further serve to improve the alignment of the deposition mask MSK. For example, the deposition mask MSK may be aligned with the deposition target so that the protrusion is accommodated in the alignment groove ALH. Accordingly, misalignment of the deposition mask MSK may be prevented.

In some embodiments, the alignment groove ALH may not overlap the first opening patterns OP1 in a plan view. For example, in FIG. 3, among the first opening patterns OP1, (1-1)th to (1-6)th opening patterns OP1-1, OP1-2, OP1-3, OP1-4, OP1-5, and OP1-6 are shown. The alignment groove ALH may be provided between (1-1)th, (1-2)th, (1-4)th, and (1-5)th opening patterns OP1-1, OP1-2, OP1-4, and OP1-5 that are adjacent to each other and between (1-2)th, (1-3)th, (1-5)th, and (1-6)th opening patterns OP1-2, OP1-3, OP1-5, and OP1-6 that are adjacent to each other. In this way, multiple alignment grooves ALH may be provided so as not to overlap the first opening patterns OP1.

Hereinafter, a method of forming a display panel including pixels using the deposition mask MSK will be described.

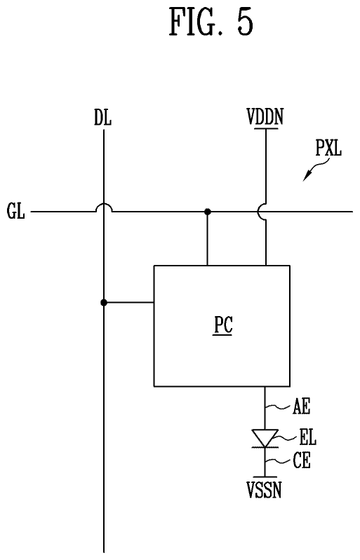

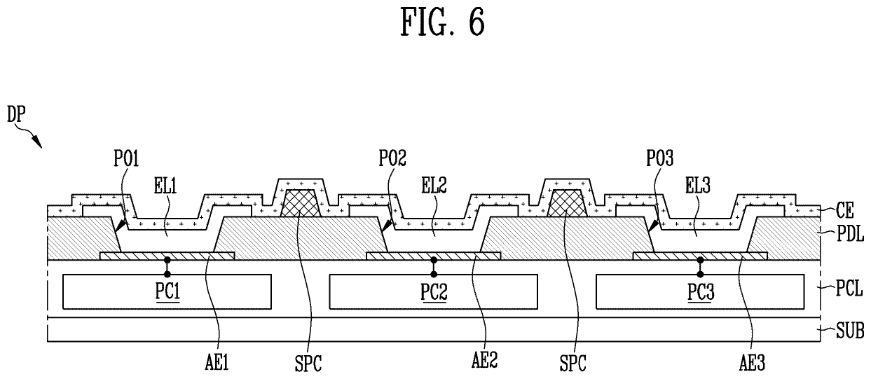

First, a display panel including pixels will be described with reference to FIGS. 5 and 6.

FIG. 5 is a schematic diagram for explaining a pixel according to embodiments of the disclosure.

Referring to FIG. 5, a pixel PXL may include a pixel circuit PC and an organic light emitting layer EL.

The organic light emitting layer EL may be connected between a first power source voltage node VDDN and a second power source voltage node VSSN. The first power source voltage node VDDN may receive a first power source voltage. The second power source voltage node VSSN may receive a second power source voltage. The first power source voltage may have a higher voltage level than the second power source voltage.

The organic light emitting layer EL may be connected between an anode electrode AE and a cathode electrode CE. The anode electrode AE may be connected to the first power source voltage node VDDN through the pixel circuit PC. For example, the anode electrode AE may be connected to the first power source voltage node VDDN through one or more transistors included in the pixel circuit PC. The cathode electrode CE may be connected to the second power source voltage node VSSN. The organic light emitting layer EL may be configured to emit light according to the current flowing from the anode electrode AE to the cathode electrode CE.

The pixel circuit PC may be connected to a gate line GL and a data line DL. In response to a gate signal received through the gate line GL, the pixel circuit PC may control the organic light emitting layer EL to emit light according to a data signal received through the data line DL. For these operations, the pixel circuit PC may include circuit elements, such as transistors and one or more capacitors.

FIG. 6 is a schematic cross-sectional view for explaining a display panel including the pixel of FIG. 5.

Referring to FIG. 6, a display panel DP may include a substrate SUB, a pixel circuit layer PCL, first to third anode electrodes AE1, AE2, and AE3, first to third organic light emitting layers EL1, EL2, and EL3, a pixel defining layer PDL, a spacer SPC, and a cathode electrode CE.

The pixel circuit layer PCL may be disposed on the substrate SUB.

The substrate SUB may be made of an insulating material such as glass or a resin. For example, the substrate SUB may include a glass substrate. In another embodiment, the substrate SUB may include a polyimide (PI) substrate. In another embodiment, the substrate SUB may include a silicon wafer substrate formed using a semiconductor process.

The pixel circuit layer PCL may include insulating layers, and semiconductor patterns and conductive patterns disposed between the insulating layers. The conductive patterns of the pixel circuit layer PCL may function as circuit elements, wirings, and the like. The circuit elements of the pixel circuit layer PCL may define first to third pixel circuits PC1, PC2, and PC3. Each of the first to third pixel circuits PC1, PC2, and PC3 may be connected to the gate line GL, the data line DL, and the first power source voltage node VDDN of FIG. 5.

First to third anode electrodes AE1, AE2, and AE3 may be disposed on the pixel circuit layer PCL. The first anode electrode AE1 may be connected to the first pixel circuit PC1. The second anode electrode AE2 may be connected to the second pixel circuit PC2. The third anode electrode AE3 may be connected to the third pixel circuit PC3.

The pixel defining layer PDL may be disposed on the pixel circuit layer PCL and the first to third anode electrodes AE1, AE2, and AE3. The pixel defining layer PDL may include first to third pixel openings PO1, PO2, and PO3 that expose portions of the first to third anode electrodes AE1, AE2, and AE3. The pixel defining layer PDL may include a light blocking material to prevent light mixing between adjacent pixels. In some embodiments, the pixel defining layer PDL may include an organic material. For example, the pixel defining layer PDL may include an organic material such as an acryl resin, an epoxy resin, a phenol resin, a polyamide resin, and a polyimide resin.

The first organic light emitting layer EL1 may be disposed on the first anode electrode AE1 exposed by the first pixel opening PO1 and a side surface of the pixel defining layer PDL adjacent to the first anode electrode AE1. The second organic light emitting layer EL2 may be disposed on the second anode electrode AE2 exposed by the second pixel opening PO2 and a side surface of the pixel defining layer PDL adjacent to the second anode electrode AE2. The third organic light emitting layer EL3 may be disposed on the third anode electrode AE3 exposed by the third pixel opening PO3 and a side surface of the pixel defining layer PDL adjacent to the third anode electrode AE3. The first to third organic light emitting layers EL1, EL2, and EL3 may include an organic material capable of emitting light based on signals provided from the first to third anode electrodes AE1, AE2, and AE3.

The spacer SPC may be disposed on the pixel defining layer PDL between the first to third pixel openings PO1, PO2, and PO3. The spacer SPC may protrude in a direction away from the pixel circuit layer PCL. The spacer SPC may serve to prevent lateral leakage current between adjacent pixels.

The cathode electrode CE may be disposed to cover the pixel defining layer PDL, the first to third organic light emitting layers EL1, EL2, and EL3, and the spacer SPC. The cathode electrode CE may be connected to the first to third organic light emitting layers EL1, EL2, and EL3. As such, the cathode electrode CE may be a common electrode commonly provided for the first to third organic light emitting layers EL1, EL2, and EL3. The cathode electrode CE may be connected to the second power source voltage node VSSN of FIG. 5.

A first pixel including the first pixel circuit PC1, the first anode electrode AE1, the cathode electrode CE, and the first organic light emitting layer EL1 interposed between the first anode electrode AE1 and the cathode electrode CE may be provided. Likewise, a second pixel including the second pixel circuit PC2, the second anode electrode AE2, the cathode electrode CE, and the second organic light emitting layer EL2 interposed between the second anode electrode AE2 and the cathode electrode CE may be provided. Likewise, a third pixel including the third pixel circuit PC3, the third anode electrode AE3, the cathode electrode CE, and the third organic light emitting layer EL3 interposed between the third anode electrode AE3 and the cathode electrode CE may be provided.

FIGS. 7 to 9 are schematic cross-sectional views for explaining a method of manufacturing the display panel of FIG. 6 using the deposition mask of FIG. 1.

Referring to FIG. 7, the display panel DP including the substrate SUB, the pixel circuit layer PCL, the first to third anode electrodes AE1, AE2, and AE3, the pixel defining layer PDL, and the spacer SPC may be provided.

The deposition mask MSK may be provided to face the display panel DP. For example, the inorganic layer ILL of the deposition mask MSK may be arranged to face the pixel defining layer PDL of the display panel DP.

Referring to FIG. 8, the deposition mask MSK may be aligned with the display panel DP. In an embodiment, the spacer SPC may be accommodated in the alignment groove ALH. The first opening patterns OP1 may expose the first to third pixel openings PO1, PO2, and PO3 and portions of the pixel defining layer PDL adjacent to the first to third pixel openings PO1, PO2, and PO3.

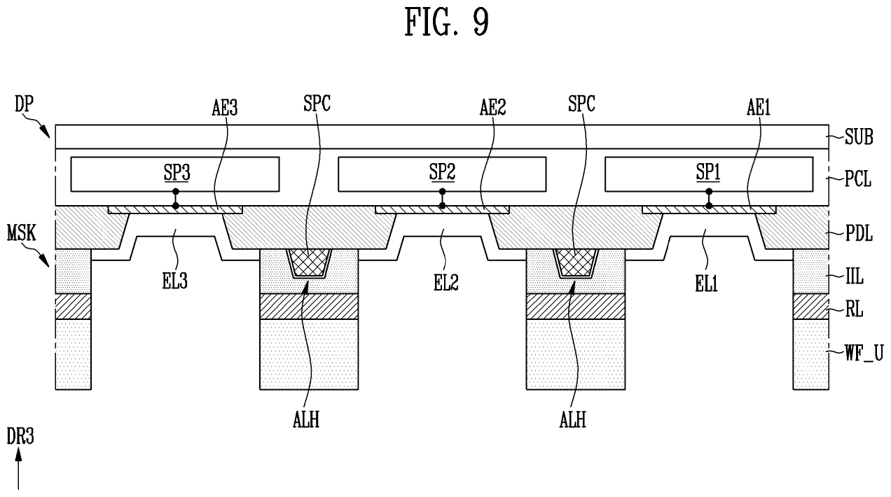

Referring to FIG. 9, the first to third organic light emitting layers EL1, EL2, and EL3 may be deposited on the first to third pixel openings PO1, PO2, and PO3 and the pixel defining layer PDL adjacent to the first to third pixel openings PO1, PO2, and PO3.

Hereinafter, the deposition mask MSK may be removed, and the cathode electrode CE described with reference to FIG. 6 may be formed.

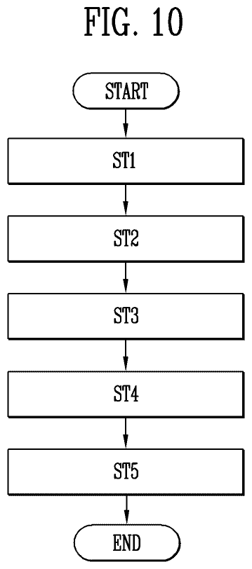

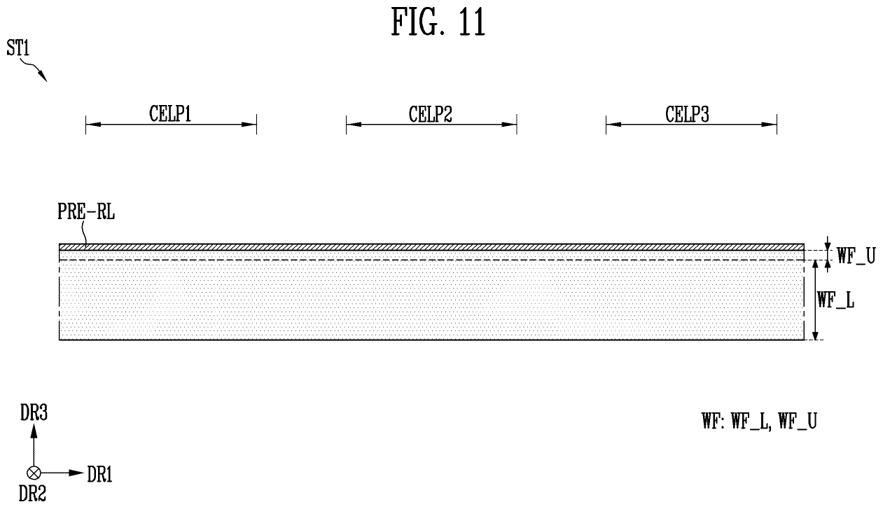

FIG. 10 is a flowchart for explaining a method of manufacturing the deposition mask of FIG. 1. FIGS. 11 to 15 are schematic cross-sectional views for explaining a method of manufacturing the deposition mask of FIG. 1. Hereinafter, descriptions of content that overlaps with the content described with reference to FIGS. 1 to 9 will be omitted.

Referring to FIG. 10, a method of manufacturing the deposition mask MSK may include first to fifth steps ST1, ST2, ST3, ST4, and ST5.

Referring to FIG. 11, a pre-deformation resistance layer PRE-RL may be formed on an entire surface of a wafer substrate WF (ST1). Here, the wafer substrate WF may include the cell opening areas CELP (see FIG. 1) described with reference to FIG. 1. In FIG. 11, first to third cell opening areas CELP1, CELP2, and CELP3 among the cell opening areas CELP are shown.

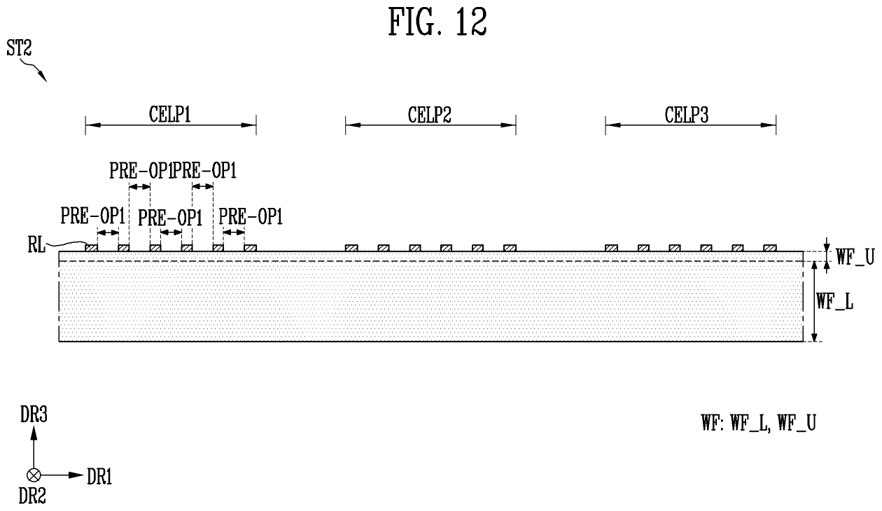

Referring to FIG. 12, by patterning the pre-deformation resistance layer PRE-RL (see FIG. 11), multiple deformation resistance layers RL may be formed (ST2). A method of patterning the pre-deformation resistance layer PRE-RL is not particularly limited, and various methods can be used. For example, after patterning the pre-deformation resistance layer PRE-RL using the exposed and developed photoresist material as a mask, the photoresist material may be removed.

The deformation resistance layers RL may overlap the first to third cell opening areas CELP1, CELP2, and CELP3 in a plan view. In an embodiment, multiple first pre-opening patterns PRE-OP1 corresponding to the first opening patterns OP1 (see FIG. 2) may be formed in the deformation resistance layers RL.

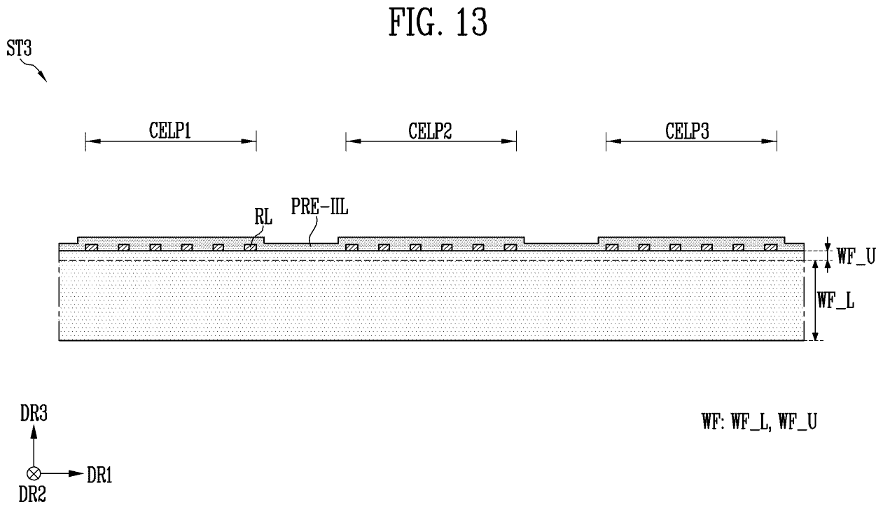

Referring to FIG. 13, a pre-inorganic layer PRE-ILL may be formed on the wafer substrate WF to cover the wafer substrate WF and the deformation resistance layers RL (ST3). A method of forming the pre-inorganic layer PRE-ILL is not particularly limited, and various methods can be used.

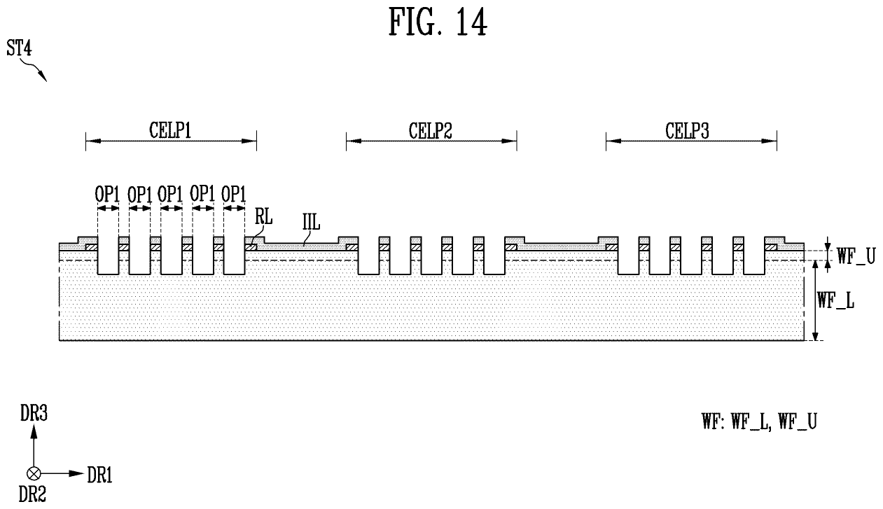

Referring to FIG. 14, in an area overlapping the first pre-opening patterns PRE-OP1 (see FIG. 12), the pre-inorganic layer PRE-ILL (see FIG. 13) and a first portion WF_U of the wafer substrate WF may be removed to form the first opening patterns OP1 (ST4).

According to embodiments, in the area overlapping the first pre-opening patterns PRE-OP1 (see FIG. 12) in a plan view, a second portion WF_L of the wafer substrate WF may be further removed. For example, the first opening patterns OP1 may further extend to the second portion WF_L.

In the fourth step (ST4), an alignment groove ALH (see FIG. 4) may be further formed. For example, while removing the pre-inorganic layer PRE-ILL (see FIG. 13) and the first portion WF_U of the wafer substrate WF, the pre-inorganic layer PRE-ILL in an area corresponding to the alignment groove ALH may be further removed selectively.

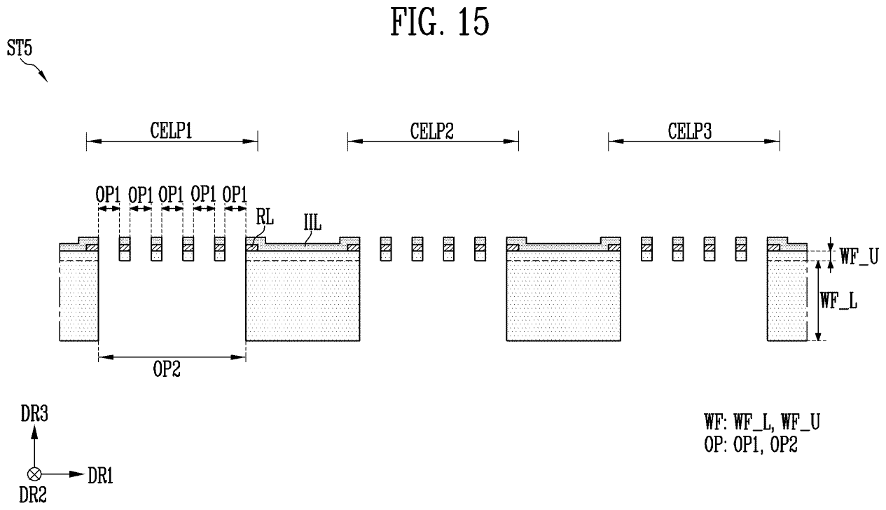

Referring to FIG. 15, in an area overlapping the first to third cell opening areas CELP1, CELP2, and CELP3 in a plan view, the second portion WF_L may be removed to form multiple second opening patterns OP2 (ST5). In an embodiment, the second portion WF_L may be sequentially removed along the third direction DR3 from a lower surface of the wafer substrate WF.

In the deposition mask according to the embodiments of the disclosure, multiple first opening patterns may be defined. A deformation resistance layer may be provided between the first opening patterns, and thus, deformation resistance of the deposition mask may be improved. Accordingly, the reliability of the deposition mask may be improved.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A deposition mask comprising:
a wafer substrate including a first portion, a second portion below the first portion, and a plurality of cell opening areas spaced apart from each other;
a plurality of deformation resistance layers disposed on the wafer substrate to overlap the plurality of cell opening areas in a plan view and corresponding one-to-one to the plurality of cell opening areas; and
an inorganic layer disposed on the wafer substrate to cover the wafer substrate and the plurality of deformation resistance layers, wherein
in each of the plurality of cell opening areas, a plurality of first opening patterns penetrating the first portion, a corresponding one of the plurality of deformation resistance layers, and the inorganic layer in a thickness direction are defined, and
a plurality of second opening patterns penetrating the second portion in the thickness direction are defined to overlap the plurality of cell opening areas in a plan view.

2. The deposition mask of claim 1, wherein the plurality of second opening patterns are provided to correspond one-to-one to the plurality of cell opening areas.

3. The deposition mask of claim 1, wherein in each of the plurality of cell opening areas, one of the plurality of second opening patterns and two or more of the plurality of first opening patterns overlap each other in a plan view.

4. The deposition mask of claim 1, wherein in each of the plurality of cell opening areas, the plurality of deformation resistance layers are disposed on the wafer substrate in an area between the plurality of first opening patterns.

5. The deposition mask of claim 4, wherein in an area between the plurality of cell opening areas, an upper surface of the wafer substrate is directly covered by the inorganic layer.

6. The deposition mask of claim 1, wherein the plurality of deformation resistance layers include a material having a thermal expansion coefficient less than or equal to about 10 in/in° C. and a Young's modulus greater than or equal to about 300 GPa.

7. The deposition mask of claim 6, wherein the plurality of deformation resistance layers include graphene.

8. The deposition mask of claim 1, wherein the inorganic layer includes at least one of silicon nitride, silicon oxide, and silicon oxynitride.

9. The deposition mask of claim 1, wherein in each of the plurality of cell opening areas, a sum of a thickness of the corresponding one of the plurality of deformation resistance layers and a thickness of the inorganic layer is less than or equal to about 1 micrometer.

10. The deposition mask of claim 1, further comprising:
an alignment groove recessed in a direction from an upper surface of the inorganic layer toward the wafer substrate.

11. The deposition mask of claim 10, wherein the alignment groove does not overlap the plurality of first opening patterns in a plan view.

12. The deposition mask of claim 11, wherein the alignment groove is located between adjacent ones of the plurality of first opening patterns in each of the plurality of cell opening areas.

13. The deposition mask of claim 1, wherein the first portion and the second portion are formed integrally.

14. A method of manufacturing a deposition mask comprising:
forming a pre-deformation resistance layer on a wafer substrate including a first portion, a second portion below the first portion, and a plurality of cell opening areas spaced apart from each other;
patterning the pre-deformation resistance layer to form a plurality of deformation resistance layers defining a plurality of first pre-opening patterns exposing an upper surface of the wafer substrate in each of the plurality of cell opening areas;
forming a pre-inorganic layer on the wafer substrate to cover the wafer substrate and the plurality of deformation resistance layers;
forming a plurality of first opening patterns by removing a portion of the pre-inorganic layer and the first portion in an area overlapping the plurality of first pre-opening patterns in a plan view; and
forming a plurality of second opening patterns by removing a portion of the second portion in an area overlapping the plurality of cell opening areas in a plan view.

15. The method of claim 14, wherein the plurality of deformation resistance layers include a material having a thermal expansion coefficient less than or equal to about 10 in/in° C. and a Young's modulus greater than or equal to about 300 GPa.

16. The method of claim 15, wherein the plurality of deformation resistance layers include graphene.

17. The method of claim 14, wherein the plurality of second opening patterns are provided to correspond one-to-one to the plurality of cell opening areas.

18. The method of claim 14, wherein in each of the plurality of cell opening areas, one of the plurality of second opening patterns and two or more of the plurality of first opening patterns overlap each other in a plan view.

19. The method of claim 14, further comprising:
forming an alignment groove recessed in a direction from an upper surface of the inorganic layer toward the wafer substrate.
